(19) United States
(12) Patent Application Publication
(10) Pub. No.: US 2025/0070037 A1
(43) Pub. Date: Feb. 27, 2025

(54) RADIO FREQUENCY MODULE

(71) Applicant: Murata Manufacturing Co., Ltd., Kyoto (JP)

(72) Inventors: Yoshihito OTSUBO, Kyoto (JP); Hiroki YOSHIMORI, Kyoto (JP)

(21) Appl. No.: 18/947,350

(22) Filed: Nov. 14, 2024

Related U.S. Application Data
(63) Continuation of application No. PCT/JP2023/017876, filed on May 12, 2023.

(30) Foreign Application Priority Data
May 19, 2022 (JP) 2022-082646

(51) Int. Cl. H01L 23/538; H01L 23/552; H01L 25/16

(52) U.S. Cl. CPC H01L 23/5386; H01L 23/5383; H01L 23/552; H01L 25/16; H01L 28/10; H01L 28/60

(57) ABSTRACT

In a radio frequency module, a magnetic core included in an inductor is disposed inside a through hole of a core board. An axis of winding of a coil is perpendicular to a thickness direction defined for the core board. A magnetic core has a first side surface and a second side surface intersecting with the axis of winding of the coil. A first shield portion includes a first feedthrough ground via conductor provided for the core board. A second shield portion includes a second feedthrough ground via conductor provided for the core board. The first feedthrough ground via conductor and the second feedthrough ground via conductor are arranged to interpose the magnetic core between the first feedthrough ground via conductor and the second feedthrough ground via conductor in a direction aligned with the axis of winding of the coil.

### CROSS REFERENCE TO RELATED APPLICATION

This is a continuation of International Application No. PCT/JP2023/017876 filed on May 12, 2023 which claims priority from Japanese Patent Application No. 2022-082646 filed on May 19, 2022. The contents of these applications are incorporated herein by reference in their entireties.

### BACKGROUND OF THE DISCLOSURE

### Field of the Disclosure

The present disclosure generally relates to a radio frequency (RF) module and more particularly relates to an RF module including a core board and a plurality of buildup layers.

### Description of the Related Art

JP 2018-508989 A discloses an integrated device package including a package board (wiring board), dies (electronic components) mounted on the package board, and a magnetic core inductor.

The package board may include, for example: a first dielectric layer serving as a core layer; a second dielectric layer formed on a first surface of the first dielectric layer, a cavity of the first dielectric layer, and a magnetic core; and a third dielectric layer formed on a second surface of the first dielectric layer. The magnetic core inductor (inductor) is embedded in the package board. The magnetic core of the magnetic core inductor is disposed inside the cavity of the first dielectric layer.

### BRIEF SUMMARY OF THE DISCLOSURE

In the known RF module, noise may be generated due to a magnetic flux line produced by the inductor, thus possibly causing a decline in the characteristics of the RF module.

A possible benefit of the present disclosure is to provide an RF module which may reduce the chances of causing a decline in the characteristics of the RF module.

A radio frequency module according to an aspect of the present disclosure includes a wiring board, an electronic component, an inductor, and a first shield portion and a second shield portion. The electronic component is disposed on the wiring board. The inductor is built in the wiring board. The wiring board includes a core board, a first buildup layer, and a second buildup layer. The core board has not only a first principal surface and a second principal surface facing each other but also a through hole. The first buildup layer is stacked on the first principal surface of the core board. The second buildup layer is stacked on the second principal surface of the core board. The inductor includes a magnetic core and a coil. The magnetic core is disposed inside the through hole of the core board. The coil is wound around the magnetic core. In this radio frequency module, an axis of winding of the coil is perpendicular to a thickness direction defined for the core board. The first shield portion includes a first feedthrough ground via conductor. The first feedthrough ground via conductor is provided for the core board. The second shield portion includes a second feedthrough ground via conductor. The second feedthrough ground via conductor is provided for the core board. The first feedthrough ground via conductor and the second feedthrough ground via conductor are arranged to interpose the magnetic core between the first feedthrough ground via conductor and the second feedthrough ground via conductor in a direction aligned with the axis of winding.

A radio frequency module according to another aspect of the present disclosure includes a wiring board, an electronic component, an inductor, and a first shield portion and a second shield portion. The electronic component is disposed on the wiring board. The inductor is built in the wiring board. The wiring board includes a core board, a first buildup layer, and a second buildup layer. The core board has not only a first principal surface and a second principal surface facing each other but also a through hole. The first buildup layer is stacked on the first principal surface of the core board. The second buildup layer is stacked on the second principal surface of the core board. The inductor includes a magnetic core and a coil. The magnetic core is disposed inside the through hole of the core board. The coil is wound around the magnetic core. In this radio frequency module, an axis of winding of the coil is parallel to a thickness direction defined for the core board. The first shield portion includes a first ground conductor portion. The first ground conductor portion is provided for the first buildup layer. The second shield portion includes a second ground conductor portion. The second ground conductor portion is provided for the second buildup layer. The first ground conductor portion and the second ground conductor portion are arranged to interpose the magnetic core between the first ground conductor portion and the second ground conductor portion in a direction aligned with the axis of winding.

An RF module according to the above-described aspect of the present disclosure may reduce the chances of causing a decline in the characteristics of the RF module.

### BRIEF DESCRIPTION OF THE SEVERAL VIEWS OF THE DRAWINGS

FIG. 1 is a cross-sectional view of an RF module according to a first embodiment;

FIG. 2A is a plan view illustrating a main part of the RF module;

FIG. 2B is a cross-sectional view of the main part of the RF module;

FIG. 3A is a cross-sectional view of the RF module taken along the plane X1-X1 shown in FIG. 2A;

FIG. 3B is a cross-sectional view of the RF module taken along the plane X2-X2 shown in FIG. 2A;

FIG. 4 is a plan view illustrating a main part of an RF module according to a variation of the first embodiment;

FIG. 5 is a cross-sectional view of an RF module according to a second embodiment;

FIG. 6 is a cross-sectional view of an RF module according to a third embodiment;

FIG. 7 is a cross-sectional view of an RF module according to a fourth embodiment;

FIG. 8A is a plan view illustrating a main part of the RF module;

FIG. 8B is a bottom view of the main part of the RF module;

FIG. 9 is a plan view illustrating a main part of an RF module according to a variation of the fourth embodiment; and

FIG. 10 is a cross-sectional view of an RF module according to a fifth embodiment.

### DETAILED DESCRIPTION OF THE DISCLOSURE

The drawings to be referred to in the following description of first to fifth embodiments are all schematic representations. Thus, the ratio of the dimensions (including thicknesses) of respective constituent elements illustrated on the drawings does not always reflect their actual dimensional ratio.

### First Embodiment

### (1) Overview

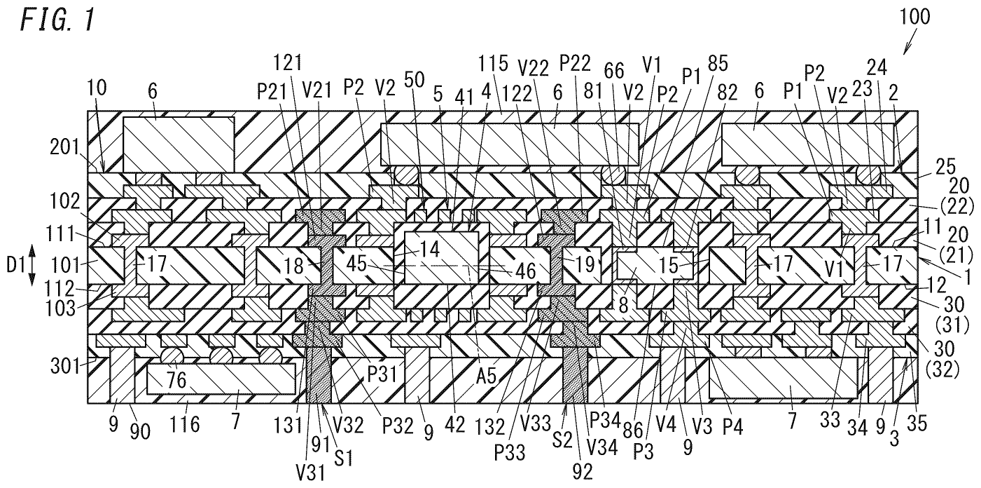

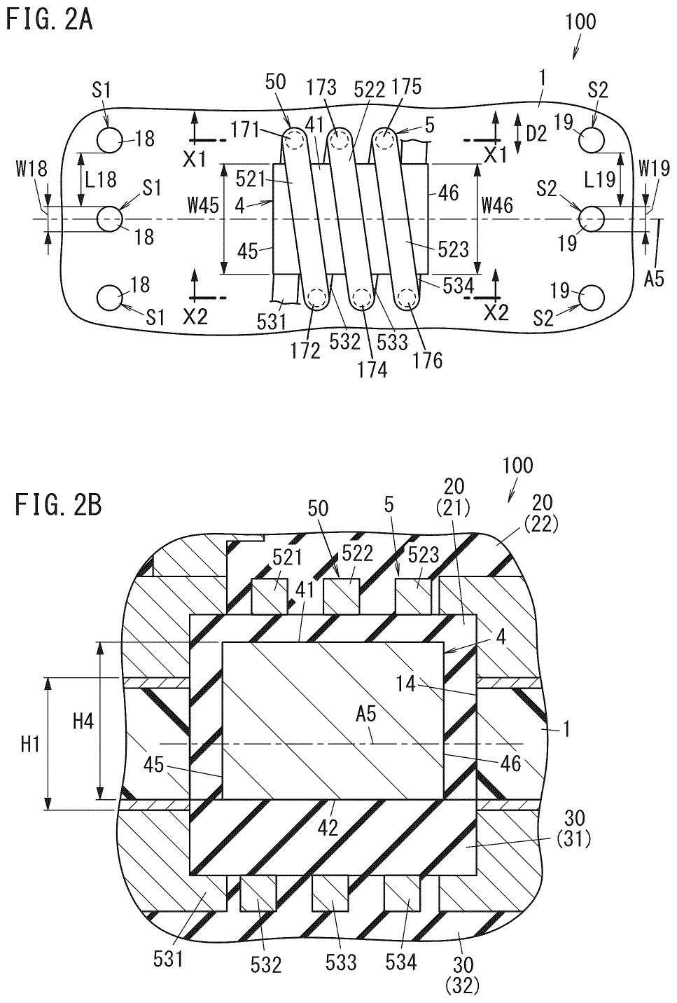

As shown in FIG. 1, an RF module 100 according to a first embodiment includes a wiring board 10, a plurality of electronic components 6, an inductor 50, a plurality of (e.g., three in FIG. 2A) first shield portions S1, and a plurality of (e.g., three in FIG. 2A) second shield portions S2. The plurality of electronic components 6 are arranged on the wiring board 10. The inductor 50 is built in the wiring board 10.

The wiring board 10 includes a core board 1, a first buildup layer 2, and a second buildup layer 3. The core board 1 has not only a first principal surface 11 and a second principal surface 12 facing each other but also a through hole 14 as well. As used herein, the phrase “facing each other” refers to facing each other geometrically, not physically. The first buildup layer 2 is stacked on the first principal surface 11 of the core board 1. The second buildup layer 3 is stacked on the second principal surface 12 of the core board 1. The plurality of electronic components 6 (hereinafter referred to as “first electronic components 6”) are arranged on one principal surface 201, opposite from the other principal surface facing the core board 1, of the first buildup layer 2.

The inductor 50 includes a magnetic core 4 and a coil 5. The magnetic core 4 has a third principal surface 41 and a fourth principal surface 42 facing each other and is disposed inside a through hole 14 of the core board 1. The coil 5 is wound around the magnetic core 4. In the RF module 100, the axis of winding A5 of the coil 5 is perpendicular to a thickness direction D1 defined for the core board 1. As used herein, the expression “the axis of winding A5 of the coil 5 is perpendicular to the thickness direction D1 defined for the core board 1” refers to not only a situation where the axis of winding A5 and the thickness direction D1 intersect with each other at exactly right angles but also a situation where the angle formed between the axis of winding A5 of the coil 5 and the thickness direction D1 defined for the core board 1 is equal to or greater than 85 degrees and equal to or less than 95 degrees. When viewed in plan in the thickness direction D1 defined for the core board 1, the plurality of first shield portions S1 and the plurality of second shield portions S2 are arranged to surround the coil 5. In other words, when viewed in plan in the thickness direction D1 defined for the core board 1, the coil 5 is located between the plurality of first shield portions S1 and the plurality of second shield portions S2 in a direction aligned with the axis of winding A5 of the coil 5.

In addition, the RF module 100 further includes a plurality of second electronic components 7, a plurality of external connection terminals 9, a first resin layer 115, and a second resin layer 116. The plurality of second electronic components 7 are arranged on the second buildup layer 3. The plurality of external connection terminals 9 are arranged on the second buildup layer 3. The first resin layer 115 is arranged on the first buildup layer 2 to cover the respective first electronic components 6 partially. The second resin layer 116 is arranged on the second buildup layer 3 to cover respective parts of the external connection terminals 9 and the second electronic components 7.

The RF module 100 may be used, for example, in a communications device. The communications device may be, without limitation, a cellphone (such as a smartphone), for example. Alternatively, the communications device may also be a wearable terminal (such as a smartwatch). The RF module 100 is a module compatible with, for example, a fourth-generation mobile communications (4G) standard or a fifth-generation mobile communications (5G) standard. Examples of the 4G standard include the third-generation partnership project (3GPP (R)) standard and the long-term evolution (LTE (R)) standard. Examples of the 5G standards include the 5G new radio (NR) standard. The RF module 100 is a module compatible with the carrier aggregation and dual connectivity, for example.

### (2) Details

Next, an RF module 100 according to a first embodiment will be described in further detail with reference to FIGS. 1, 2A, and 2B

### (2.1) Core Board

As shown in FIG. 1, the core board 1 has a first principal surface 11 and a second principal surface 12. When viewed in plan in the thickness direction D1 defined for the core board 1, the outer edges of the core board 1 have a quadrangular shape, for example.

The core board 1 includes a dielectric substrate 101, a first conductive layer 102, a second conductive layer 103, and a plurality of feedthrough via conductors 17. In the core board 1, the first conductive layer 102 is disposed on a first principal surface 111 of the dielectric substrate 101 and the second conductive layer 103 is disposed on a second principal surface 112 of the dielectric substrate 101. Each of the first conductive layer 102 and the second conductive layer 103 is formed to have one or more predetermined patterns which are defined on a layer-by-layer basis. The core board 1 may be, for example, a double-sided printed wiring board. Examples of materials for the dielectric substrate 101 include an epoxy resin, a polyimide resin, and a composite material of an epoxy resin and a glass fiber. A material for the first conductive layer 102 and the second conductive layer 103 may be copper, for example. A material for the plurality of feedthrough via conductors 17 may include copper, for example.

The first principal surface 11 and second principal surface 12 of the core board 1 face each other in the thickness direction D1 defined for the core board 1. Optionally, the first principal surface 11 and second principal surface 12 of the core board 1 may have microscopic unevenness or have only microscopic recesses or projections.

The core board 1 has a first through hole 14 and a second through hole 15. The magnetic core 4 is disposed inside the first through hole 14 of the core board 1. A capacitor 8 is disposed inside the second through hole 15 of the core board 1.

### (2.2) Capacitor

The capacitor 8 is a chip capacitor. The capacitor 8 includes a first electrode 81 and a second electrode 82. The capacitor 8 has a substantially rectangular parallelepiped outer shape. A part of the first dielectric layer 20 of the first buildup layer 2 is located between the capacitor 8 and an inner peripheral surface of the second through hole 15 of the core board 1. The capacitor 8 has a fifth principal surface 85 and a sixth principal surface 86 facing each other in the thickness direction D1 defined for the core board 1. The capacitor 8 is connected to the coil 5. In addition, the capacitor 8 is also connected to at least one of the plurality of first electronic components 6. The RF module 100 includes a matching circuit including the inductor 50 and the capacitor 8. In other words, in the RF module 100, the inductor 50 and the capacitor 8 are circuit elements which form the matching circuit. Examples of the first electronic components 6, to which the matching circuit including the coil 5 and the capacitor 8 is connected, include a power amplifier, a low-noise amplifier, a filter, and a switch. The switch may be, for example, a switch integrated circuit (IC) including a common terminal and a plurality of selection terminals which may be connected to the common terminal.

### (2.3) First Buildup Layer

The first buildup layer 2 is stacked on the first principal surface 11 of the core board 1, the third principal surface 41 of the magnetic core 4, and the fifth principal surface 85 of the capacitor 8. The first buildup layer 2 includes a plurality of (e.g., two) first dielectric layers 20. If the two first dielectric layers 20 need to be distinguished from each other, then the two first dielectric layers 20 will be hereinafter referred to as a first dielectric layer 21 and a first dielectric layer 22, respectively. In the first buildup layer 2, the first dielectric layer 21 is a first dielectric layer 20 located closest to the first principal surface 11 of the core board 1 in the thickness direction D1 defined for the core board 1. Also, in the first buildup layer 2, the first dielectric layer 22 is a first dielectric layer 20 located most distant from the first principal surface 11 of the core board 1 in the thickness direction D1 defined for the core board 1.

In addition, the first buildup layer 2 further includes a plurality of (e.g., two) first conductor layers 23, 24. The first conductor layer 23 is interposed between the first dielectric layers 21, 22. The first conductor layer 24 is formed on the first dielectric layer 22. These two first conductor layers 23, 24 are formed in one or more predetermined patterns which are defined on a layer-by-layer basis. The first conductor layer 23 includes one or more rewiring portions (conductor portions) P1 as the one or more predetermined patterns. The first conductor layer 24 includes one or more rewiring portions (conductor portions) P2 as the one or more predetermined patterns. In addition, the first buildup layer 2 further includes a plurality of via conductors V1 that connect the first conductor layer 23 and the first conductive layer 102 of the core board 1 to each other and a plurality of via conductors V2 that connect the first conductor layers 24, 23 to each other.

Examples of materials for the plurality of first dielectric layers 20 include an epoxy resin, a phenolic resin, a urethane resin, a silicone resin, and a polyimide resin. A material for the plurality of first conductor layers 23, 24 may include, for example, copper.

In addition, the first buildup layer 2 further includes a first resist layer 25. The first resist layer 25 is stacked on the first dielectric layer 22 and the first conductor layer 24. The first resist layer 25 is formed in a predetermined pattern and has a plurality of openings that expose respective parts of the plurality of rewiring portions P2. The first resist layer 25 may be, for example, a solder resist layer. A material for the first resist layer 25 may be a material having a lower degree of solder wettability than the first conductor layer 24. Examples of materials for the first resist layer 25 include a polyimide resin and an epoxy resin.

### (2.4) Second Buildup Layer

The second buildup layer 3 is stacked on the second principal surface 12 of the core board 1 and the fourth principal surface 42 of the magnetic core 4. The second buildup layer 2 includes a plurality of (e.g., two) second dielectric layers 30. If the two second dielectric layers 30 need to be distinguished from each other, then the two second dielectric layers 30 will be hereinafter referred to as a second dielectric layer 31 and a second dielectric layer 32, respectively. In the second buildup layer 3, the second dielectric layer 31 is a second dielectric layer 30 located closest to the second principal surface 12 of the core board 1 in the thickness direction D1 defined for the core board 1. Also, in the second buildup layer 3, the second dielectric layer 32 is a second dielectric layer 30 located most distant from the second principal surface 12 of the core board 1 in the thickness direction D1 defined for the core board 1.

In addition, the second buildup layer 3 further includes a plurality of (e.g., two) second conductor layers 33, 34. The second conductor layer 33 is interposed between the second dielectric layers 31, 32. The second conductor layer 34 is formed on the second dielectric layer 32. These two second conductor layers 33, 34 are formed in one or more predetermined patterns which are defined on a layer-by-layer basis. The second conductor layer 33 includes one or more rewiring portions (conductor portions) P3 as the one or more predetermined patterns. The second conductor layer 34 includes one or more rewiring portions (conductor portions) P4 as the one or more predetermined patterns. In addition, the second buildup layer 3 further includes a plurality of via conductors V3 that connect the second conductor layer 33 and the second conductive layer 103 of the core board 1 to each other and a plurality of via conductors V4 that connect the second conductor layers 34, 33 to each other.

Examples of materials for the plurality of second dielectric layers 30 include an epoxy resin, a phenolic resin, a urethane resin, a silicone resin, and a polyimide resin. A material for the plurality of second conductor layers 33, 34 may include, for example, copper.

In addition, the second buildup layer 3 further includes a second resist layer 35. The second resist layer 35 is stacked on the second dielectric layer 32 and the second conductor layer 34. The second resist layer 35 is formed in a predetermined pattern and has a plurality of openings that expose respective parts of the plurality of rewiring portions P4. The second resist layer 35 may be, for example, a solder resist layer. A material for the second resist layer 35 may be a material having a lower degree of solder wettability than the second conductor layer 34. Examples of materials for the second resist layer 35 include a polyimide resin and an epoxy resin.

### (2.5) Inductor

The inductor 50 includes the magnetic core 4 and the coil 5 as described above.

The magnetic core 4 is disposed inside the first through hole 14 of the core board 1. When viewed in plan in the thickness direction D1 defined for the core board 1, the outer edges of the magnetic core 4 may have, for example, a quadrangular shape. The magnetic core 4 has the third principal surface 41 and the fourth principal surface 42 facing each other in the thickness direction D1 defined for the core board 1. In addition, the magnetic core 4 further has a first side surface 45 and a second side surface 46 which intersect with the axis of winding A5 of the coil 5. A part of the first dielectric layer 20 of the first buildup layer 2 is interposed between the first side surface 45 and second side surface 46 of the magnetic core 4 and the inner peripheral surface of the first through hole 14 of the core board 1. Also, when measured in the thickness direction D1 defined for the core board 1, the thickness H4 of the magnetic core 4 (refer to FIG. 2B) is greater than the thickness H1 of the core board 1 (refer to FIG. 2B). From the viewpoint of improving the characteristics of the inductor 50, the first side surface 45 and second side surface 46 of the magnetic core 4 preferably have as large an area as possible.

A material for the magnetic core 4 includes a magnetic material. Examples of the magnetic material include a ferrite, a permalloy, an iron-based amorphous alloy, a cobalt-based amorphous alloy, and a nickel-based amorphous alloy.

The coil 5 is wound around the magnetic core 4. The coil 5 is provided to cover the core board 1, the first buildup layer 2, and the second buildup layer 3. That is to say, the coil 5 is provided for the wiring board 10 including the core board 1, the first buildup layer 2, and the second buildup layer 3 to partially surround the magnetic core 4. The coil 5 may be, for example, a solenoid coil.

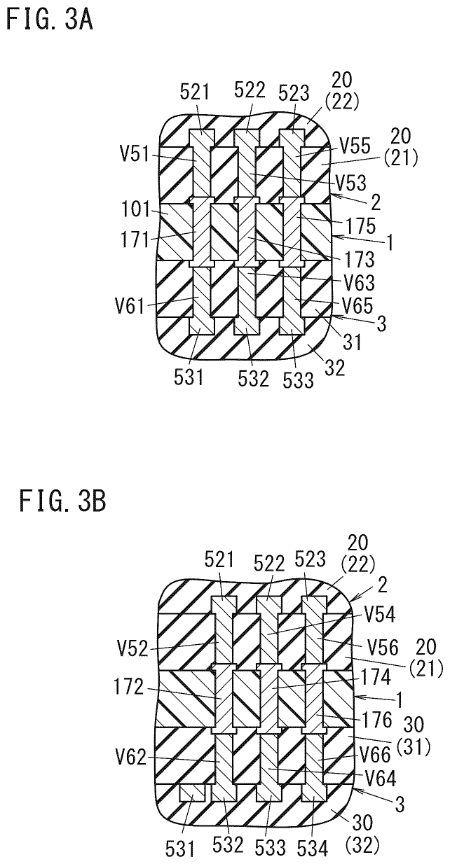

As shown in FIGS. 2A, 2B, 3A, and 3B, the coil 5 includes a plurality of (e.g., six) feedthrough via conductors 171-176, a plurality of (e.g., six) first via conductors V51-V56 and a plurality of (e.g., three) first conductor portions 521-523, and a plurality of (e.g., six) second via conductors V61-V66 and a plurality of (e.g., four) second conductor portions 531-534.

The plurality of (e.g., six) feedthrough via conductors 171-176 are provided for the core board 1. The plurality of (e.g., six) first via conductors V51-V56 and the plurality of (e.g., three) first conductor portions 521-523 are provided for the first buildup layer 2. The plurality of (e.g., six) second via conductors V61-V66 and the plurality of (e.g., four) second conductor portions 531-534 are provided for the second buildup layer 3. The plurality of (e.g., six) feedthrough via conductors 171-176 of the coil 5 penetrate through the dielectric substrate 101 of the core board 1. The plurality of first via conductors V51-V56 of the coil 5 penetrate through the first dielectric layer 21 of the first buildup layer 2. The plurality of second via conductors V61-V66 of the coil 5 penetrate through the second dielectric layer 31 of the second buildup layer 3. The plurality of first conductor portions 521-523 of the coil 5 are formed in the first dielectric layer 21. A part of the first dielectric layer 21 is interposed between the plurality of first conductor portions 521-523 of the coil 5 and the third principal surface 41 of the magnetic core 4. The plurality of second conductor portions 531-534 of the coil 5 are formed in the second dielectric layer 31. A part of the second dielectric layer 31 is interposed between the plurality of second conductor portions 531-534 of the coil 5 and the fourth principal surface 42 of the magnetic core 4.

A material for the plurality of feedthrough via conductors 171-176 is the same as the material for the plurality of feedthrough via conductors 17, the first feedthrough ground via conductor 18, and the second feedthrough ground via conductor 19 of the core board 1. The material for the plurality of feedthrough via conductors 171-176 may include, for example, copper.

A material for the plurality of first via conductors V51-V56 is the same as the material for the plurality of via conductors V1 of the first buildup layer 2. The material for the plurality of first via conductors V51-V56 may include, for example, copper.

A material for the plurality of first conductor portions 521-523 is the same as the material for the plurality of rewiring portions P1 of the first buildup layer 2. The material for the plurality of first conductor portions 521-523 may include, for example, copper.

A material for the plurality of second via conductors V61-V66 is the same as the material for the plurality of via conductors V3 of the second buildup layer 3. The material for the plurality of second via conductors V61-V66 may include, for example, copper.

A material for the plurality of second conductor portions 531-534 is the same as the material for the plurality of rewiring portions P3 of the second buildup layer 3. The material for the plurality of second conductor portions 531-534 may include, for example, copper.

When viewed in plan in the thickness direction D1 defined for the core board 1, each of the plurality of first via conductors V51-V56 and the plurality of second via conductors V61-V66 may have, for example, a circular shape.

### (2.6) First Electronic Components

As shown in FIG. 1, the plurality of first electronic components 6 are arranged on the wiring board 10. More specifically, the plurality of first electronic components 6 are arranged on the first buildup layer 2. The first electronic components 6 may be, for example, IC chips or surface mount electronic components. Examples of the IC chips include a power amplifier, a low-noise amplifier, a switch, and a controller. Examples of the surface mount electronic components include a chip inductor and a chip capacitor. Alternatively, the first electronic components 6 may each be a filter, a multiplexer, or a coupler, for example. Examples of the filter include a surface acoustic wave filter, a bulk acoustic wave filter, and an LC filter. Optionally, each of the first electronic components 6 may also be an electronic component including a plurality of filters. As used herein, the expression “the first electronic components 6 are arranged on the first buildup layer 2” refers to both a situation where the first electronic components 6 are mounted on (i.e., mechanically connected to) the first buildup layer 2 and a situation where the first electronic components 6 are electrically connected to (appropriate rewiring portions P2 of) the first buildup layer 2. The first electronic components 6 are mounted on the second principal surface 201 of the first buildup layer 2 by bonding the first electronic components 6 to the plurality of rewiring portions P2 of the first buildup layer 2 via a plurality of bonding portions 66, for example. A material for the plurality of bonding portions 66 may be solder, for example. The plurality of bonding portions 66 may be constituent elements of the first electronic components 6 or constituent elements interposed between the first electronic components 6 and the principal surface 201 of the first buildup layer 2, whichever is appropriate. If the plurality of bonding portions 66 are constituent elements of the first electronic components 6, then the plurality of bonding portions 66 are conductive bumps.

### (2.7) Second Electronic Components

The plurality of second electronic components 7 are arranged on the wiring board 10. More specifically, the plurality of second electronic components 7 are arranged on the second buildup layer 3. The second electronic components 7 may be, for example, IC chips or surface mount electronic components. Examples of the IC chips include a power amplifier, a low-noise amplifier, a switch, and a controller. Examples of the surface mount electronic components include a chip inductor and a chip capacitor. The second electronic components 7 may each be, for example, a filter, a multiplexer, or a coupler. The filter may be, for example, a surface acoustic wave filter, a bulk acoustic wave filter, or an LC filter. Optionally, each of the second electronic components 7 may also be an electronic component including a plurality of filters. As used herein, the expression “the second electronic components 7 are arranged on the second buildup layer 3” refers to both a situation where the second electronic components 7 are mounted (i.e., mechanically connected) onto the second buildup layer 3 and a situation where the second electronic components 7 are electrically connected to (appropriate rewiring portions P4 of) the second buildup layer 3. The second electronic components 7 are mounted on the principal surface 301 of the second buildup layer 3 by bonding the second electronic components 7 to the plurality of rewiring portions P4 of the second buildup layer 3 via a plurality of bonding portions 76, for example. A material for the plurality of bonding portions 76 may be solder, for example. The plurality of bonding portions 76 may be constituent elements of the second electronic components 7 or constituent elements interposed between the second electronic components 7 and the principal surface 301 of the second buildup layer 3, whichever is appropriate. If the plurality of bonding portions 76 are constituent elements of the second electronic components 7, then the plurality of bonding portions 76 are conductive bumps.

### (2.6) External Connection Terminals

The plurality of external connection terminals 9 are arranged on the second buildup layer 3. As used herein, the expression “the external connection terminals 9 are arranged on the second buildup layer 3” refers to both a situation where the external connection terminals 9 are mechanically connected to the second buildup layer 3 and a situation where the external connection terminals 9 are electrically connected to (appropriate rewiring portions P4 of) the second buildup layer 3. The plurality of external connection terminals 9 includes a first ground terminal 91 and a second ground terminal 92. The first ground terminal 91 and the second ground terminal 92 may each be, for example, a terminal which is electrically connected to a ground electrode of a circuit board included in the communications device to be supplied with a ground potential. In addition, the plurality of external connection terminals 9 includes an antenna terminal connected to an antenna provided outside of the RF module 100, a signal input terminal connected to an input terminal of a power amplifier, and a signal output terminal connected to an output terminal of a low-noise amplifier. A material for the plurality of external connection terminals 9 may be, for example, a metal (such as copper or a copper alloy). Each of the plurality of external connection terminals 9 is a columnar electrode. The columnar electrode may be, for example, a circular columnar electrode. The plurality of external connection terminals 9 may be bonded, via solder, for example, to the rewiring portions P4 of the second buildup layer 3. However, this is only an example and should not be construed as limiting. Alternatively, the plurality of external connection terminals 9 may also be bonded to the rewiring portions P4 via a conductive adhesive (such as conductive paste) or bonded thereto directly, whichever is appropriate. Each of the plurality of external connection terminals 9 has a circular shape when viewed in plan in the thickness direction D1 defined for the core board 1.

### (2.7) First Resin Layer

The first resin layer 115 is disposed on the first buildup layer 2. The first resin layer 115 covers the plurality of first electronic components 6 mounted on the first buildup layer 2. The first resin layer 115 contains a resin (such as an epoxy resin). The first resin layer 115 may contain not only the resin but also a filler as well.

### (2.8) Second Resin Layer

The second resin layer 116 covers the plurality of second electronic components 7 arranged on the second buildup layer 3. In addition, the second resin layer 116 also covers the side surfaces of the plurality of external connection terminals 9. Nevertheless, the second resin layer 116 does not cover the end face 90, facing away from the second buildup layer 3, of the plurality of external connection terminals 9. The second resin layer 116 contains a resin (such as an epoxy resin). The second resin layer 116 may contain not only the resin but also a filler as well. A material for the second resin layer 116 may be the same as, or different from, the material for the first resin layer 115, whichever is appropriate.

### (2.11) First Shield Portion and Second Shield Portion

In this RF module 100, when viewed in plan in the thickness direction D1 defined for the core board 1, the coil 5 is located between the plurality of first shield portions S1 and the plurality of second shield portions S2 in a direction aligned with the axis of winding A5 of the coil 5 as described above. In this RF module 100, no electronic components are arranged between the plurality of first shield portions S1 and the coil 5 and the first side surface 45 of the magnetic core 4. Likewise, in this RF module 100, no electronic components are arranged, either, between the plurality of second shield portions S2 and the coil 5 and the second side surface 46 of the magnetic core 4.

Each of the first shield portions S1 includes a first feedthrough ground via conductor 18. The first feedthrough ground via conductor 18 is provided for the core board 1 and is located closer to the first side surface 45 of the magnetic core 4 rather than to the second side surface 46 thereof in the direction aligned with the axis of winding A5 of the coil 5. Each of the second shield portions S2 includes a second feedthrough ground via conductor 19. The second feedthrough ground via conductor 19 is provided for the core board 1 and is located closer to the second side surface 46 of the magnetic core 4 rather than to the first side surface 45 thereof in the direction aligned with the axis of winding A5 of the coil 5. The first feedthrough ground via conductors 18 and the second feedthrough ground via conductors 19 penetrate through the dielectric substrate 101 of the core board 1. Each of the first feedthrough ground via conductors 18 and the second feedthrough ground via conductors 19 may have, for example, a circular columnar shape. A material for the first feedthrough ground via conductors 18 and the second feedthrough ground via conductors 19 is the same as the material for the feedthrough via conductors 17 of the core board 1.

Each of the first shield portions S1 further includes a ground conductor portion 121 and a ground conductor portion 131 which are connected to the first feedthrough ground via conductors 18. The ground conductor portion 121 and the ground conductor portion 131 are provided for the core board 1 and are laid on top of a corresponding one of the first feedthrough ground via conductors 18 in the thickness direction D1 defined for the core board 1. A part of the ground conductor portion 121 is disposed on the first principal surface 111 of the dielectric substrate 101 of the core board 1. A material for the ground conductor portion 121 is the same as the material for the first conductive layer 102. A part of the ground conductor portion 131 is disposed on the second principal surface 112 of the dielectric substrate 101 of the core board 1. A material for the ground conductor portion 131 is the same as the material for the second conductive layer 103 of the core board 1.

Each of the first shield portions S1 further includes a grounding via conductor V21 and a grounding conductor portion P21. The grounding via conductor V21 and the grounding conductor portion P21 are provided for the first buildup layer 2. The grounding via conductor V21 penetrates through the first dielectric layer 21. The grounding conductor portion P21 is formed on the first dielectric layer 21 and is connected to the grounding via conductor V21. The grounding via conductor V21 and the grounding conductor portion P21 are laid on top of a corresponding one of the first feedthrough ground via conductors 18 in the thickness direction D1 defined for the core board 1. A material for the grounding via conductor V21 and the grounding conductor portion P21 is the same as the material for the via conductors V1 and the rewiring portions P1.

Each of the first shield portions S1 further includes a grounding via conductor V31 and a grounding conductor portion P31. The grounding via conductor V31 and the grounding conductor portion P31 are provided for the second buildup layer 3. The grounding via conductor V31 penetrates through the second dielectric layer 31. The grounding conductor portion P31 is stacked on the second dielectric layer 31 and is connected to the grounding via conductor V31. The grounding via conductor V31 and the grounding conductor portion P31 are laid on top of a corresponding one of the first feedthrough ground via conductors 18 in the thickness direction D1 defined for the core board 1. A material for the grounding via conductor V31 and the grounding conductor portion P31 is the same as the material for the via conductors V3 and the rewiring portions P3.

Each of the first shield portions S1 further includes a grounding via conductor V32 and a grounding conductor portion P32. The grounding via conductor V32 and the grounding conductor portion P32 are provided for the second buildup layer 3. The grounding via conductor V32 penetrates through the second dielectric layer 32. The grounding conductor portion P32 is stacked on the second dielectric layer 32 and is connected to the grounding via conductor V32. The grounding via conductor V32 and the grounding conductor portion P32 are laid on top of a corresponding one of the first feedthrough ground via conductors 18 in the thickness direction D1 defined for the core board 1. A material for the grounding via conductor V32 and the grounding conductor portion P32 is the same as the material for the via conductors V4 and the rewiring portions P4. Each of the first shield portions S1 further includes a first ground terminal 91 connected to the first feedthrough ground via conductors 18. The first ground terminal 91 is connected to the first feedthrough ground via conductors 18 via the grounding conductor portion P32, the grounding via conductor V32, the grounding conductor portion P31, the grounding via conductor V31, and the ground conductor portion 131. The first ground terminal 91 is laid on top of a corresponding one of the first feedthrough ground via conductors 18 in the thickness direction D1 defined for the core board 1. A material for the first ground terminal 91 is the same as the material for the external connection terminal 9. The plurality of first shield portions S1 overlap with a part of the coil 5 in side view in a direction aligned with the axis of winding A5 of the coil 5.

Each of the second shield portions S2 further includes a ground conductor portion 122 and a ground conductor portion 132 which are connected to the second feedthrough ground via conductors 19. The ground conductor portion 122 and the ground conductor portion 132 are provided for the core board 1 and laid on top of a corresponding one of the second feedthrough ground via conductors 19 in the thickness direction D1 defined for the core board 1. A part of the ground conductor portion 122 is disposed on the first principal surface 111 of the dielectric substrate 101 of the core board 1. A material for the ground conductor portion 122 is the same as the material for the first conductive layer 102. A part of the ground conductor portion 122 is disposed on the second principal surface 112 of the dielectric substrate 101 of the core board 1. A material for the ground conductor portion 132 is the same as the material for the second conductive layer 103 of the core board 1.

Each of the second shield portions S2 further includes a grounding via conductor V22 and a grounding conductor portion P22. The grounding via conductor V22 and the grounding conductor portion P22 are provided for the first buildup layer 2. The grounding via conductor V22 penetrates through the first dielectric layer 22. The grounding conductor portion P22 is stacked on the first dielectric layer 21 and is connected to the grounding via conductor V22. The grounding via conductor V22 and the grounding conductor portion P22 are laid on top of a corresponding one of the second feedthrough ground via conductors 19 in the thickness direction D1 defined for the core board 1. A material for the grounding via conductor V22 and the grounding conductor portion P22 is the same as the material for the via conductors V2 and the rewiring portions P2.

Each of the second shield portions S2 further includes a grounding via conductor V33 and a grounding conductor portion P33. The grounding via conductor V33 and the grounding conductor portion P33 are provided for the second buildup layer 3. The grounding via conductor V33 penetrates through the second dielectric layer 31. The grounding conductor portion P33 is stacked on the second dielectric layer 31 and is connected to the grounding via conductor V33. The grounding via conductor V33 and the grounding conductor portion P33 are laid on top of a corresponding one of the second feedthrough ground via conductors 19 in the thickness direction D1 defined for the core board 1. A material for the grounding via conductor V33 and the grounding conductor portion P33 is the same as the material for the via conductors V3 and the rewiring portions P3.

Each of the second shield portions S2 further includes a grounding via conductor V34 and a grounding conductor portion P34. The grounding via conductor V34 and the grounding conductor portion P34 are provided for the second buildup layer 3. The grounding via conductor V34 penetrates through the second dielectric layer 32. The grounding conductor portion P34 is stacked on the second dielectric layer 32 and is connected to the grounding via conductor V34. The grounding via conductor V34 and the grounding conductor portion P34 are laid on top of a corresponding one of the second feedthrough ground via conductors 19 in the thickness direction D1 defined for the core board 1. A material for the grounding via conductor V34 and the grounding conductor portion P34 is the same as the material for the via conductors V4 and the rewiring portions P4.

Each of the second shield portions S2 further includes a second ground terminal 92 connected to the second feedthrough ground via conductors 19. The second ground terminal 92 is connected to the second feedthrough ground via conductors 19 via the grounding conductor portion P34, the grounding via conductor V34, the grounding conductor portion P33, the grounding via conductor V33, and the ground conductor portion 132. The second ground terminal 92 is laid on top of with the second feedthrough ground via conductors 19 in the thickness direction D1 defined for the core board 1. A material for the second ground terminals 92 is the same as the material for the external connection terminals 9. The plurality of second shield portions S2 overlap with a part of the coil 5 in side view in a direction aligned with the axis of winding A5 of the coil 5.

As shown in FIG. 2A, when viewed in plan in the thickness direction D1 defined for the core board 1 (hereinafter referred to as a “first direction D1”), the length W18 of each first feedthrough ground via conductor 18 as measured in a second direction D2 perpendicular to the axis of winding A5 of the coil 5 is shorter than the length W45 of the first side surface 45 of the magnetic core 4 as measured in the second direction D2. In addition, as shown in FIG. 2A, when viewed in plan in the first direction D1, the length W19 of each second feedthrough ground via conductor 19 as measured in the second direction D2 is shorter than the length W46 of the second side surface 46 of the magnetic core 4 as measured in the second direction D2.

In the example shown in FIG. 2A, the number of the first shield portions S1 provided is the same as the number of the second shield portions S2 provided. Note that the number of the first shield portions S1 provided and the number of the second shield portions S2 provided do not have to be the same but may also be different from each other. The plurality of first shield portions S1 are arranged side by side in the second direction D2 when viewed in plan in the thickness direction D1 defined for the core board 1. The gap distance L18 between two first shield portions S1 belonging to the plurality of first shield portions S1 which are adjacent to each other in the second direction D2 may be, for example, equal to or greater than λ/4, where λ is the wavelength of radio frequency noise which would be generated by the coil 5. The plurality of second shield portions S2 are arranged side by side in the second direction D2 when viewed in plan in the thickness direction D1 defined for the core board 1. The gap distance L19 between two second shield portions S2 belonging to the plurality of second shield portions S2 which are adjacent to each other in the second direction D2 may be, for example. equal to or greater than λ/4.

One of the plurality of first feedthrough ground via conductors 18 and one of the plurality of second feedthrough ground via conductors 19 are located on the axis of winding A5 of the coil 5 when viewed in plan in the thickness direction D1 defined for the core board 1.

### (3) Advantages

In the RF module 100 according to the first embodiment, the axis of winding A5 of the coil 5 and the thickness direction D1 defined for the core board 1 are perpendicular to each other. Each of the first shield portions S1 includes the first feedthrough ground via conductor 18. The first feedthrough ground via conductor 18 is provided for the core board 1. Each of the second shield portions S2 includes the second feedthrough ground via conductor 19. The second feedthrough ground via conductor 19 is provided for the core board 1. The first feedthrough ground via conductor 18 and the second feedthrough ground via conductor 19 are arranged to interpose the magnetic core 4 between the first feedthrough ground via conductor 18 and the second feedthrough ground via conductor 19 in a direction aligned with the axis of winding A5 of the coil 5.

The RF module 100 according to the first embodiment may reduce the chances of causing a decline in the characteristics of the RF module 100. More specifically, in this RF module 100, a current flowing through the coil 5 makes the orientation of the magnetic flux generated by the coil 5 aligned with the axis of winding A5 of the coil 5 in the magnetic core 4. In this RF module 100, each of the first shield portions S1 includes the first feedthrough ground via conductor 18 and each of the second shield portions S2 includes the second feedthrough ground via conductor 19. Thus, the RF module 100 may reduce the decline in isolation due to the magnetic flux generated in the inductor 50 by the current flowing through the coil 5. In addition, in this RF module 100, each of the first shield portions S1 includes the first feedthrough ground via conductor 18 and each of the second shield portions S2 includes the second feedthrough ground via conductor 19. This may reduce the chances of an eddy current being produced by the magnetic flux generated in the inductor 50, compared to a situation where the first shield portion S1 and the second shield portion S2 have the shape of a wall larger in size than the magnetic core 4 in side view in the direction aligned with the axis of winding A5 of the coil 5. Consequently, this may reduce the chances of causing a decline in the characteristics of the inductor 50.

In addition, in this RF module 100, when measured in the thickness direction D1 defined for the core board 1, the thickness H4 of the magnetic core 4 is greater than the thickness H1 of the core board 1. This allows the RF module 100 to improve the characteristics of the inductor 50 compared to a situation where the thickness H4 of the magnetic core 4 is equal to or less than the thickness H1 of the core board 1.

Furthermore, this RF module 100 includes a plurality of first feedthrough ground via conductors 18, which are arranged side by side in a direction (i.e., the second direction D2) perpendicular to both the thickness direction D1 defined for the core board 1 and the axis of winding A5 of the coil 5. This RF module 100 also includes a plurality of second feedthrough ground via conductors 19, which are arranged side by side in the direction (i.e., the second direction D2) perpendicular to both the thickness direction D1 defined for the core board 1 and the axis of winding A5 of the coil 5. Thus, the RF module 100 may further reduce the chances of causing a decline in the characteristics of the RF module 100 due to the magnetic flux generated in the coil 5 by the current flowing through the coil 5.

Furthermore, the RF module 100 further includes second electronic components 7. Thus, the RF module 100 may contribute to reducing the size of the RF module 100 when viewed in plan in the thickness direction D1 defined for the core board 1.

Furthermore, in this RF module 100, one of the plurality of via conductors V1 included in the first buildup layer 2 is directly connected to the first electrode 81 of the capacitor 8 and another one of the via conductors V1 is directly connected to the second electrode 82 of the capacitor 8. Besides, in this RF module 100, one of the plurality of via conductors V3 included in the second buildup layer 3 is directly connected to the first electrode 81 of the capacitor 8 and another one of the via conductors V3 is directly connected to the second electrode 82 of the capacitor 8. This allows the RF module 100 to adopt a configuration including no members for electrically connecting the first electrode 81 and second electrode 82 of the capacitor 8 to the core board 1.

### Variation of First Embodiment

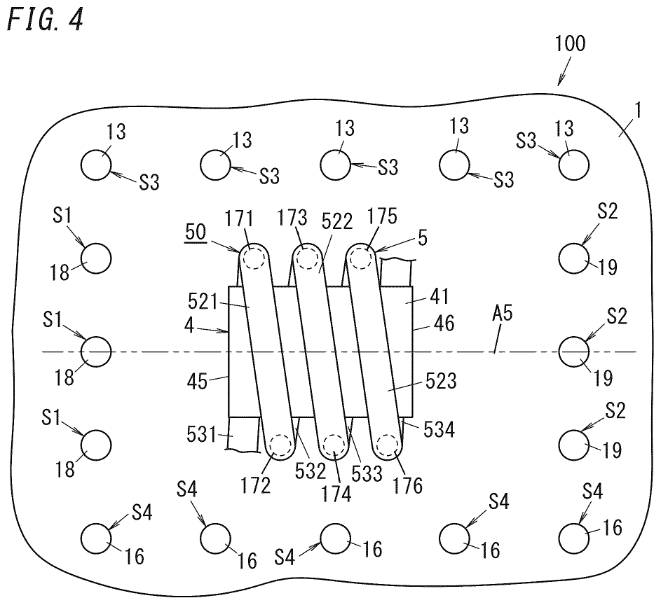

An RF module 100 according to a variation of the first embodiment further includes a plurality of (e.g., five) third shield portions S3 and a plurality of (e.g., five) fourth shield portions S4, all of which are arranged side by side in a direction parallel to the axis of winding A5 of the coil 5 as shown in FIG. 4. Each of the third shield portions S3 includes a third feedthrough ground via conductor 13 provided for the core board 1. In the RF module 100 according to this variation, the coil 5 and the magnetic core 4 are located between the plurality of third shield portions S3 and the plurality of fourth shield portions S4 in the second direction D2. In addition, in the RF module 100 according to the variation, when viewed in plan in the thickness direction D1 defined for the core board 1 (refer to FIG. 1), the coil 5 and the magnetic core 4 are surrounded with a plurality of shield portions including the plurality of first shield portions S1, the plurality of second shield portions S2, the plurality of third shield portions S3, and the plurality of fourth shield portions S4. When viewed in plan in the thickness direction D1 defined for the core board 1, each of the plurality of third shield portions S3 includes a third ground terminal (not shown) connected to the third feedthrough ground via conductor 13 of the third shield portion S3. Each of the plurality of fourth shield portions S4 includes a fourth feedthrough ground via conductor 16 provided for the core board 1. Each of the plurality of fourth shield portions S4 includes a fourth ground terminal (not shown) connected to the fourth feedthrough ground via conductor 16 of the fourth shield portion S4. Each of the plurality of third shield portions S3 and the plurality of fourth shield portions S4 has the same structure as the first shield portion S1.

In the RF module 100 according to this variation, when viewed in plan in the thickness direction D1 defined for the core board 1, the plurality of first feedthrough ground via conductors 18, the plurality of second feedthrough ground via conductors 19, the plurality of third feedthrough ground via conductors 13, and the plurality of fourth feedthrough ground via conductors 16 are arranged to surround the magnetic core 4 and the coil 5.

Thus, the RF module 100 according to this variation may further reduce the chances of causing a decline in the characteristics of the RF module 100 due to the magnetic flux generated in the coil 5 by the current flowing through the coil 5.

### Second Embodiment

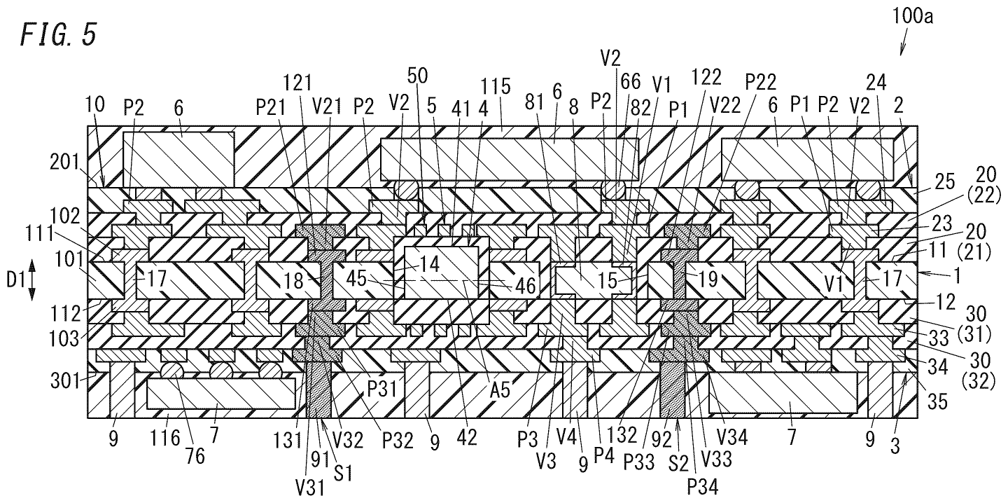

An RF module 100a according to a second embodiment will be described with reference to FIG. 5. In the following description, any constituent element of the RF module 100a according to the second embodiment, having the same function as a counterpart of the RF module 100 (refer to FIG. 1) according to the first embodiment described above, will be designated by the same reference numeral as that counterpart's, and description thereof will be omitted herein.

### (1) Configuration

In an RF module 100a according to the second embodiment, when viewed in plan in the thickness direction D1 defined for the core board 1, the capacitor 8 is located between the magnetic core 4 and the second feedthrough ground via conductors 19. Thus, in this RF module 100a, the first shield portions S1, the magnetic core 4, the capacitor 8, and the second shield portions S2 are arranged side by side in this order in a direction aligned with the axis of winding A5 of the coil 5.

### (2) Advantages

In the RF module 100a according to the second embodiment, when viewed in plan in the thickness direction D1 defined for the core board 1, the capacitor 8 is located between the magnetic core 4 and the second feedthrough ground via conductors 19, thus enabling shortening the wire length between the coil 5 and the capacitor 8.

In addition, in the first buildup layer 2 of the RF module 100a, one of the plurality of via conductors V1 included in the first buildup layer 2 is directly connected to the first electrode 81 of the capacitor 8 and another one of the via conductors V1 is directly connected to the second electrode 82 of the capacitor 8. Besides, in the second buildup layer 3, one of the plurality of via conductors V3 included in the second buildup layer 3 is directly connected to the first electrode 81 of the capacitor 8 and another one of the via conductors V3 is directly connected to the second electrode 82 of the capacitor 8. This allows the RF module 100a to adopt a configuration including no members for electrically connecting the first electrode 81 and second electrode 82 of the capacitor 8 to the core board 1.

### Third Embodiment

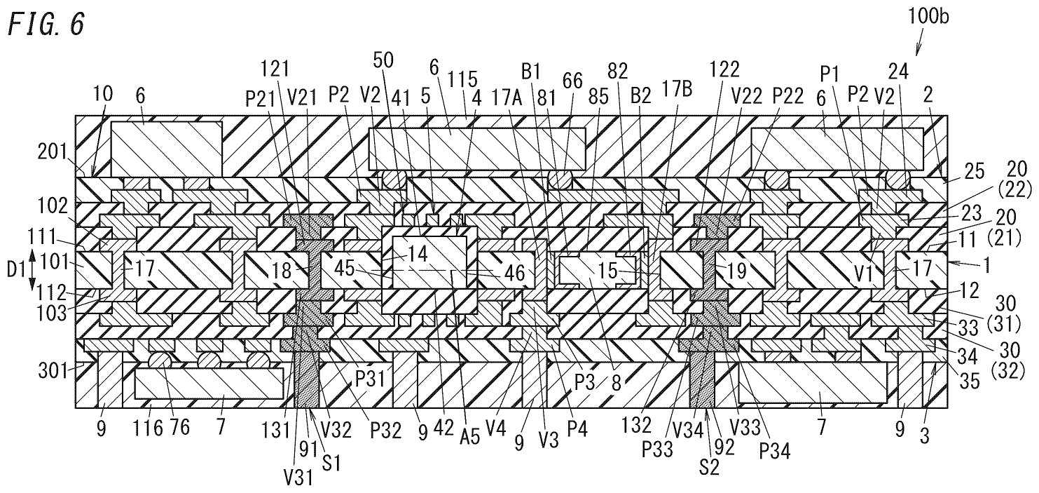

An RF module 100b according to a third embodiment will be described with reference to FIG. 6. In the following description, any constituent element of the RF module 100b according to the third embodiment, having the same function as a counterpart of the RF module 100 (refer to FIG. 1) according to the first embodiment described above, will be designated by the same reference numeral as that counterpart's, and description thereof will be omitted herein.

### (1) Configuration

In an RF module 100b according to the third embodiment, when viewed in plan in the thickness direction D1 defined for the core board 1, the capacitor 8 is located between the magnetic core 4 and the second feedthrough ground via conductors 19. Thus, in this RF module 100b, the first shield portions S1, the magnetic core 4, the capacitor 8, and the second shield portions S2 are arranged side by side in this order in the direction aligned with the axis of winding A5 of the coil 5.

In the RF module 100b according to the third embodiment, when viewed in plan in the thickness direction D1 defined for the core board 1, the capacitor 8 is located between the magnetic core 4 and the second feedthrough ground via conductors 19, thus enabling shortening the wire length between the coil 5 and the capacitor 8.

In this RF module 100b, the core board 1 further includes a first connection via conductor 17A connected to the first electrode 81 of the capacitor 8 and a second connection via conductor 17B connected to the second electrode 82 of the capacitor 8. The RF module 100b further includes a first connection portion B1 interposed between the first electrode 81 of the capacitor 8 and the first connection via conductor 17A of the core board 1. In addition, the RF module 100b further includes a second connection portion B2 interposed between the second electrode 82 of the capacitor 8 and the second connection via conductor 17B of the core board 1. Each of the first connection portion B1 and the second connection portion B2 has electrical conductivity. A material for each of the first connection portion B1 and the second connection portion B2 includes solder, for example.

### (2) Advantages

In this RF module 100b, the core board 1 includes the first connection via conductor 17A and the second connection via conductor 17B. Thus, the RF module 100b may adopt a configuration in which the capacitor 8 and the core board 1 are connected to each other.

### Fourth Embodiment

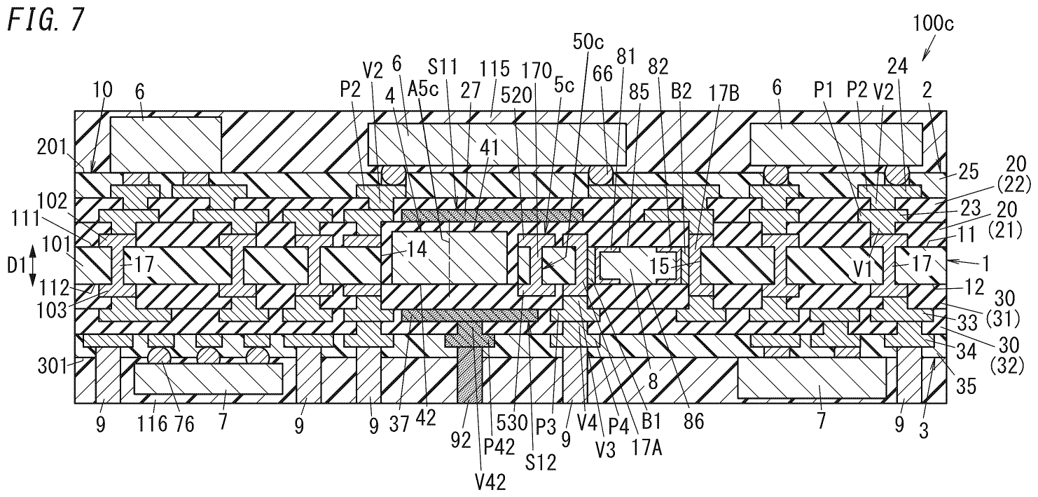

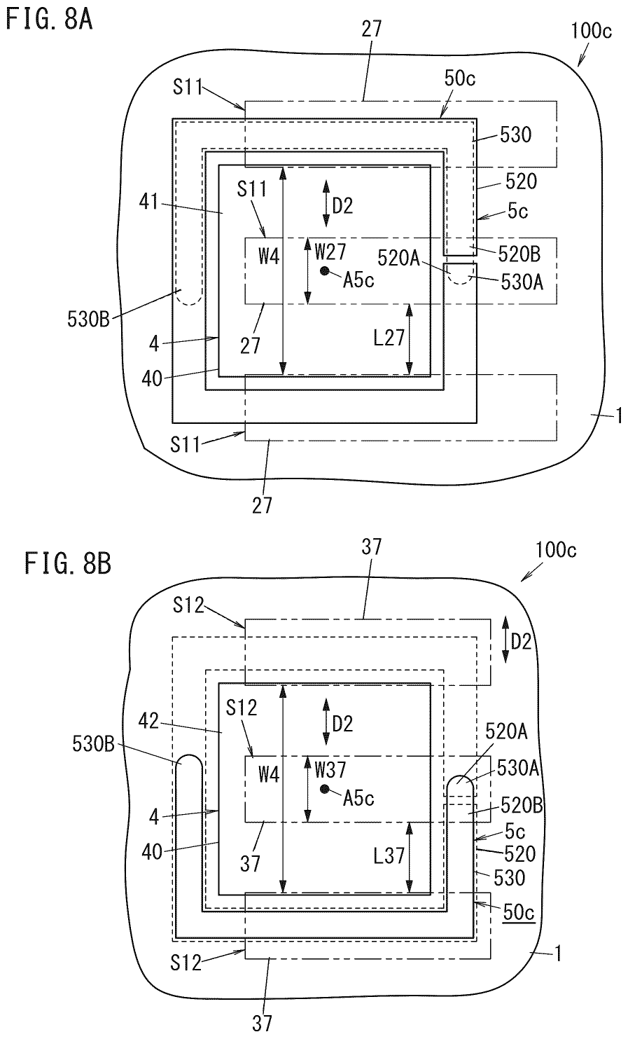

An RF module 100c according to a fourth embodiment will be described with reference to FIGS. 7, 8A, and 8B. In the following description, any constituent element of the RF module 100c according to the fourth embodiment, having the same function as a counterpart of the RF module 100 (refer to FIG. 1) according to the first embodiment described above, will be designated by the same reference numeral as that counterpart's, and description thereof will be omitted herein.

### (1) Configuration

The RF module 100c includes a coil 5c instead of the coil 5 according to the first embodiment. The RF module 100c includes an inductor 50c instead of the inductor 50 according to the first embodiment. The inductor 50c includes the magnetic core 4 and the coil 5c. The RF module 100c includes a plurality of (e.g., three in FIG. 8A) first shield portions S11 and a plurality of (e.g., three in FIG. 8B) second shield portions S12 instead of the plurality of first shield portions S1 and the plurality of second shield portions S2 according to the first embodiment. In addition, in the RF module 100c, the core board 1 further includes a first connection via conductor 17A connected to the first electrode 81 of the capacitor 8 and a second connection via conductor 17B connected to the second electrode 82 of the capacitor 8. The RF module 100c further includes a first connection portion B1 interposed between the first electrode 81 of the capacitor 8 and the first connection via conductor 17A of the core board 1. In addition, the RF module 100c further includes a second connection portion B2 interposed between the second electrode 82 of the capacitor 8 and the second connection via conductor 17B of the core board 1. Each of the first connection portion B1 and the second connection portion B2 has electrical conductivity. A material for each of the first connection portion B1 and the second connection portion B2 includes solder, for example.

The coil 5c is wound around the magnetic core 4. In the RF module 100c, the axis of winding A5c of the coil 5c and the thickness direction D1 defined for the core board 1 are parallel to each other. As used herein, the expression “the axis of winding A5c of the coil 5c and the thickness direction D1 defined for the core board 1 are parallel to each other” refers to not only a situation where the axis of winding A5c of the coil 5 and the thickness direction D1 defined for the core board 1 are exactly parallel to each other but also a situation where the angle formed between the axis of winding A5c of the coil 5c and the thickness direction D1 defined for the core board 1 is equal to or less than 10 degrees.

The coil 5c includes a first conductor portion 520, a second conductor portion 530, and a feedthrough via conductor 170. The first conductor portion 520 is provided on the first principal surface 11 of the core board 1 and is covered with the first buildup layer 2. A material for the first conductor portion 520 is the same as the material for the first conductive layer 102 of the core board 1. The first conductor portion 520 partially surrounds the outer edges 40 of the magnetic core 4 when viewed in plan in the thickness direction D1 defined for the core board 1 (refer to FIGS. 8A and 8B). The first conductor portion 520 has a first end 520A and a second end 520B in a direction along the outer edges 40 of the magnetic core 4. The second conductor portion 530 is provided on the second principal surface 12 of the core board 1 and is covered with the second buildup layer 3. A material for the second conductor portion 530 is the same as the material for the second conductive layer 103 of the core board 1. The second conductor portion 530 partially surrounds the outer edges 40 of the magnetic core 4 when viewed in plan in the thickness direction D1 defined for the core board 1 (refer to FIGS. 8A and 8B). The second conductor portion 530 has a first end 530A and a second end 530B in a direction along the outer edges 40 of the magnetic core 4. The feedthrough via conductor 170 is provided for the core board 1 to connect the first end 520A of the first conductor portion 520 to the first end 530A of the second conductor portion 530. A material for the feedthrough via conductor 170 is the same as the material for the feedthrough via conductors 17. The first end 520A of the first conductor portion 520 and the first end 530A of the second conductor portion 530 are laid one on top of the other in the thickness direction D1 defined for the core board 1.

Each of the first shield portions S11 is provided for the first buildup layer 2 and includes a first ground conductor portion 27 (refer to FIGS. 7 and 8A) which overlaps with a part of the magnetic core 4 when viewed in plan in the thickness direction D1 defined for the core board 1. Each of the second shield portions S12 is provided for the second buildup layer 3 and includes a second ground conductor portion 37 (refer to FIGS. 7 and 8B) which overlaps with a part of the magnetic core 4 when viewed in plan in the thickness direction D1 defined for the core board 1. Each of the first shield portions S11 includes a first ground terminal (not shown) arranged to face the principal surface 301 of the second buildup layer 3. In each of the first shield portions S11, the first ground conductor portion 27 is connected to the first ground terminal. Each of the second shield portions S12 includes a second ground terminal 92. In each of the second shield portions S12, the second ground conductor portion 37 is connected to the second ground terminal 92. Each of the second shield portions S12 includes the second ground conductor portion 37, a grounding via conductor V42, a grounding conductor portion P42, and the second ground terminal 92. The grounding via conductor V42 penetrates through the second dielectric layer 32 and is connected to the second ground conductor portion 37. The grounding conductor portion P42 is formed on the second dielectric layer 32 and is connected to the grounding via conductor V42. The second ground terminal 92 is disposed on, and connected to, the grounding conductor portion P42.

As shown in FIG. 8A, the length W27 of each first ground conductor portion 27 as measured in the second direction D2 perpendicular to the axis of winding A5c of the coil 5c is less than the length W4 of the magnetic core 4 as measured in the second direction D2. Also, as shown in FIG. 8B, the length W37 of each second ground conductor portion 37 as measured in the second direction D2 is less than the length W4 of the magnetic core 4 as measured in the second direction D2.

Note that the number of the first shield portions S11 provided and the number of the second shield portions S12 provided do not have to be the same but may also be different from each other. The plurality of first shield portions S11 are arranged side by side in the second direction D2. The gap distance L27 between two first shield portions S11 belonging to the plurality of first shield portions S11 which are adjacent to each other in the second direction D2 may be, for example, equal to or greater than λ/4, where λ is the wavelength of radio frequency noise which would be generated by the coil 5. The plurality of second shield portions S12 are arranged side by side in the second direction D2. The gap distance L37 between two second shield portions S12 belonging to the plurality of second shield portions S12 which are adjacent to each other in the second direction D2 may be, for example. equal to or greater than λ/4.

### (2) Advantages

A radio frequency module 100c according to the fourth embodiment described above includes a wiring board 10, an electronic component 6, an inductor 50, and a first shield portion S11 and a second shield portion S12. The electronic component 6 is disposed on the wiring board 10. The inductor 50c is built in the wiring board 10. The wiring board 10 includes a core board 1, a first buildup layer 2, and a second buildup layer 3. The core board 1 has not only a first principal surface 11 and a second principal surface 12 facing each other but also a through hole 14. The first buildup layer 2 is stacked on the first principal surface 11 of the core board 1. The second buildup layer 3 is stacked on the second principal surface 12 of the core board 1. The inductor 50c includes a magnetic core 4 and a coil 5c. The magnetic core 4 is disposed inside the through hole 14 of the core board 1. The coil 5 is wound around the magnetic core 4. In this radio frequency module 100c, an axis of winding A5c of the coil 5c is parallel to a thickness direction D1 defined for the core board 1. The first shield portion S11 includes a first ground conductor portion 27 provided for the first buildup layer 2. The second shield portion S12 includes a second ground conductor portion 37 provided for the second buildup layer 3. In the RF module 100c, the first ground conductor portion 27 and the second ground conductor portion 37 are arranged to interpose the magnetic core 4 between the first ground conductor portion 27 and the second ground conductor portion 37 in a direction aligned with the axis of winding A5c of the coil 5c.

The RF module 100c according to the fourth embodiment may reduce the chances of causing a decline in the characteristics of the RF module 100c. More specifically, in this RF module 100c, a current flowing through the coil 5c makes the orientation of the magnetic flux generated by the coil 5c aligned with the axis of winding A5c of the coil 5c in the magnetic core 4. In this RF module 100c, each of the first shield portions S11 includes the first ground conductor portion 27 and each of the second shield portions S12 includes the second ground conductor portion 37. Thus, the RF module 100c may reduce the decline in isolation due to the magnetic flux generated in the inductor 50c by the current flowing through the coil 5c. In addition, in this RF module 100c, each of the first shield portions S11 includes the first ground conductor portion 27 and each of the second shield portions S12 includes the second ground conductor portion 37. This may reduce the chances of an eddy current being produced by the magnetic flux generated in the inductor 50c, compared to a situation where the first shield portion S11 and the second shield portion S12 have the shape of a wall larger in size than the magnetic core 4 in plan view in the direction aligned with the axis of winding A5c of the coil 5c. Consequently, this may reduce the chances of causing a decline in the characteristics of the inductor 50c. In addition, the RF module 100c according to the fourth embodiment may make the dimension of the inductor 50c as measured in the thickness direction D1 defined for the core board 1 shorter than the dimension of the inductor 50 in the RF module 100 according to the first embodiment, thus contributing to reducing the height of the RF module 100c.

In addition, in this RF module 100c, when measured in the thickness direction D1 defined for the core board 1, the thickness H4 of the magnetic core 4 (refer to FIG. 2B) is greater than the thickness H1 of the core board 1 (refer to FIG. 2B). This allows the RF module 100c to improve the characteristics of the inductor 50c compared to a situation where the thickness H4 of the magnetic core 4 is equal to or less than the thickness H1 of the core board 1.

Furthermore, in this RF module 100c, the plurality of first ground conductor portions 27 are arranged side by side in a direction (i.e., the second direction D2) perpendicular to the axis of winding A5c of the coil 5c. In addition, in this RF module 100c, the plurality of second ground conductor portions 37 are arranged side by side in the direction (i.e., the second direction D2) perpendicular to the axis of winding A5c of the coil 5c. In this embodiment, when viewed in plan in the thickness direction D1 defined for the core board 1, the plurality of first ground conductor portions 27 are arranged in stripes. Likewise, when viewed in plan in the thickness direction D1 defined for the core board 1, the plurality of second ground conductor portion 37 are also arranged in stripes. Thus, the RF module 100c may further reduce the chances of causing a decline in the characteristics of the RF module 100c due to the magnetic flux generated in the coil 5c by the current flowing through the coil 5c.

Furthermore, in the RF module 100c, the first buildup layer 2 includes a plurality of first dielectric layers 20 and the second buildup layer 3 includes a plurality of second dielectric layers 30. The first ground conductor portions 27 are formed directly on a first dielectric layer 21 belonging to the plurality of first dielectric layers 20 which is located closest to the core board 1 in the thickness direction D1 defined for the core board 1. The second ground conductor portions 37 are formed directly on a second dielectric layer 31 belonging to the plurality of second dielectric layers 30 which is located closest to the core board 1 in the thickness direction D1 defined for the core board 1. Thus, the RF module 100c may improve the shielding capability of the first shield portions S11 and the second shield portions S12.

Furthermore, the RF module 100c further includes second electronic components 7. Thus, the RF module 100c may contribute to reducing the size of the RF module 100c when viewed in plan in the thickness direction D1 defined for the core board 1.

### Variation of Fourth Embodiment

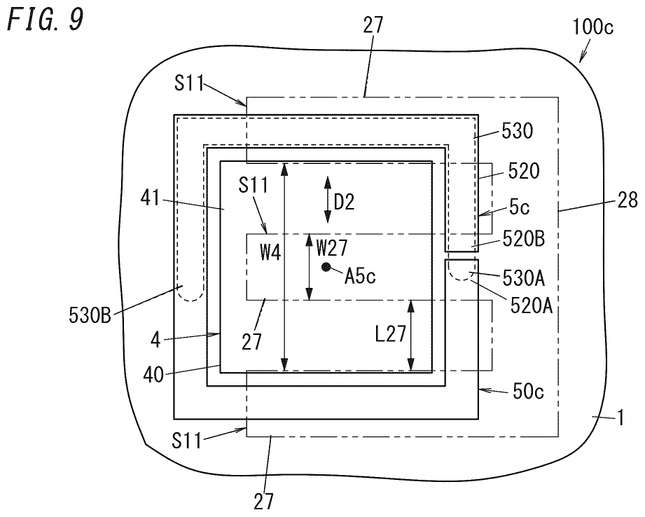

An RF module 100c according to a variation of the fourth embodiment further includes a common ground conductor portion 28 at which a plurality of (e.g., three) first ground conductor portions 27 are connected in common as shown in FIG. 9, which is a difference from the RF module 100c according to the fourth embodiment described above. In the RF module 100c according to this variation of the fourth embodiment, the assembly of the plurality of first ground conductor portions 27 and the common ground conductor portion 28 has a combtooth pattern. In this variation, when viewed in plan in the thickness direction D1 defined for the core board 1 (refer to FIG. 7), the plurality of first ground conductor portions 27 are arranged in a combtooth pattern. The RF module 100c according to this variation of the fourth embodiment allows each of the plurality of first shield portions S11 to use, in common, every constituent element (such as the first ground terminal) but the first ground conductor portions 27. Specifically, the plurality of first ground conductor portions 27 may be connected to a single first ground terminal, which is connected to the common ground conductor portion 28, via a single path between the common ground conductor portion 28 and the first ground terminal. Optionally, the RF module 100c according to this variation of the fourth embodiment may include, separately from a first common ground conductor portion 28 serving as the common ground conductor portion 28, a second common ground conductor portion to which a plurality of (e.g., three) second ground conductor portions 37 are connected in common. In that case, the assembly of the plurality of second ground conductor portions 37 and the second common ground conductor portion has a combtooth pattern. In this variation, when viewed in plan in the thickness direction D1 defined for the core board 1, the plurality of second ground conductor portions 37 are arranged in a combtooth pattern.

Furthermore, in the RF module 100c according to the fourth embodiment, the first ground conductor portions 27 have a linear shape when viewed in plan in the thickness direction D1 defined for the core board 1. However, this is only an example and should not be construed as limiting. Alternatively, the first ground conductor portions 27 may have a curved shape, for example. Also, in the RF module 100c according to the fourth embodiment, the second ground conductor portions 37 have a linear shape when viewed in plan in the thickness direction D1 defined for the core board 1. However, this is only an example and should not be construed as limiting. Alternatively, the second ground conductor portions 37 may have a curved shape, for example. Furthermore, in the RF module 100c according to the fourth embodiment, when viewed in plan in the thickness direction D1 defined for the core board 1, the longitudinal axis of the first ground conductor portions 27 and the longitudinal axis of the second ground conductor portions 37 are parallel to each other. However, this is only an example and should not be construed as limiting. Alternatively, when viewed in plan in the thickness direction D1 defined for the core board 1, the longitudinal axis of the first ground conductor portions 27 and the longitudinal axis of the second ground conductor portions 37 may intersect with each other.

### Fifth Embodiment

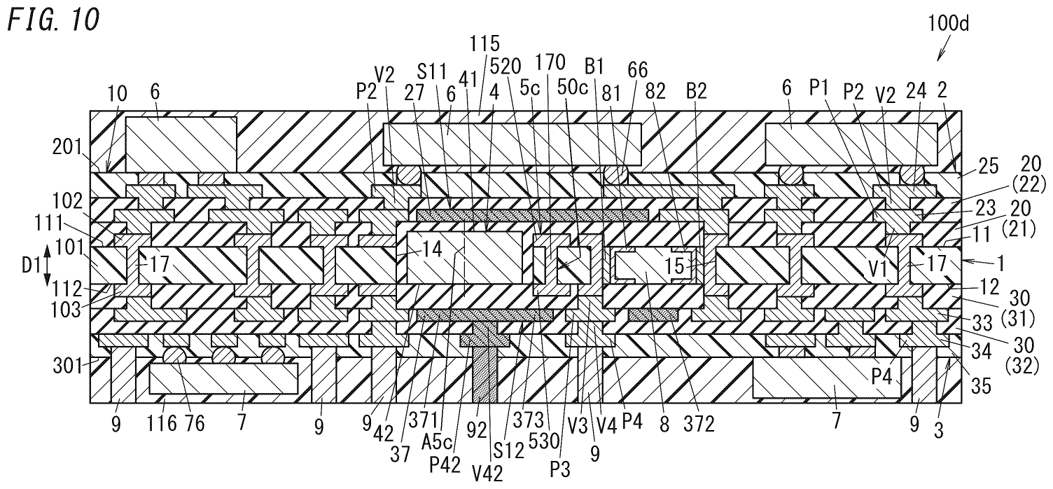

An RF module 100d according to a fifth embodiment will be described with reference to FIG. 10. In the following description, any constituent element of the RF module 100d according to the fifth embodiment, having the same function as a counterpart of the RF module 100c (refer to FIG. 7) according to the fourth embodiment described above, will be designated by the same reference numeral as that counterpart's, and description thereof will be omitted herein.

In this RF module 100d, the first ground conductor portion 27 in each of the first shield portion S11 overlaps with a part of the magnetic core 4 and a part of the capacitor 8 when viewed in plan in the thickness direction D1 defined for the core board 1. In addition, the second ground conductor portion 37 in each of the second shield portion S12 overlaps with a part of the magnetic core 4 and a part of the capacitor 8 when viewed in plan in the thickness direction D1 defined for the core board 1. The second ground conductor portion 37 includes a first part 371 which overlaps with a part of the magnetic core 4 when viewed in plan in the thickness direction D1 defined for the core board 1, a second part 372 which overlaps with a part of the capacitor 8 when viewed in plan in the thickness direction D1 defined for the core board 1, and a third part 373 which connects the first part 371 and the second part 372 to each other. As for the third part 373, the third part 373 is seen only partially in the cross-sectional view shown in FIG. 10. The first shield portions S11 and the second shield portions S12 may shield this RF module 100d from the noise generated by a matching circuit including the coil 5c and the capacitor 8.

### (Other Variations)

Note that the first to fifth embodiments described above are only exemplary ones of various embodiments of the present disclosure and should not be construed as limiting. Rather, the first to fifth embodiments may be readily modified in various manners depending on a design choice or any other factor without departing from the scope of the present disclosure. Optionally, multiple different constituent elements of mutually different embodiments may be adopted in combination as appropriate.

For example, the core board 1 does not have to be a double-sided printed wiring board but may also be a low temperature co-fired ceramic board, for example.

Also, in the RF modules 100, 100a, 100b, 100c, 100d, the outer edges of the magnetic core 4 do not have to have a quadrangular shape but may also have a hexagonal shape, for example, when viewed in plan in the thickness direction D1 defined for the core board 1. In the RF modules 100c, 100d, the outer edges of the magnetic core 4 may also have a circular shape when viewed in plan in the thickness direction D1 defined for the core board 1.

In the embodiments described above, the coil 5, 5c is a solenoid coil. However, this is only an example and should not be construed as limiting. Alternatively, the coil 5, 5c may also be a toroidal coil. In that case, the magnetic core has a ringlike shape and the axis of winding A5, A5c of the coil 5, 5c is a center axis penetrating through the center of the ringlike magnetic core. Furthermore, the coil 5 does not have to have the number of turns equal to or greater than one. Alternatively, the coil 5 may also have the number of turns less than one (e.g., three quarters or one half).

Also, in the RF modules 100, 100a, 100b, 100c, 100d, each of the plurality of external connection terminals 9 may also be a ball bump with electrical conductivity. Examples of materials for the ball bump serving as each of the plurality of external connection terminals 9 include gold, copper, and solder.

The RF modules 100, 100a, 100b, 100c, 100d each include the second electronic components 7 mounted on the principal surface 301 of the second buildup layer 3. However, this is only an example and should not be construed as limiting. Alternatively, the RF modules 100, 100a, 100b, 100c, 100d may each be configured such that the second electronic components 7 are arranged on the principal surface 201 of the first buildup layer 2 with no second electronic components 7 arranged on the principal surface 301 of the second buildup layer 3.

Furthermore, in the RF modules 100, 100a, 100b, 100c, 100d, the plurality of electronic components needs to include at least the first electronic components 6.

Furthermore, the RF modules 100, 100a, 100b, 100c, 100d may each be implemented as, for example, a transmission/reception module including a power amplifier, a transmission filter, an output matching circuit, a low-noise amplifier, a reception filter, and an input matching circuit. However, this is only an example and should not be construed as limiting. Alternatively, the RF modules 100, 100a, 100b, 100c, 100d may each be, for example, a transmission module including a power amplifier, a transmission filter, and an output matching circuit or a reception module including a low-noise amplifier, a reception filter, and an input matching circuit.

Optionally, the RF modules 100, 100a, 100b, 100c, 100d may each further include a shield layer covering the first resin layer 115, the outer peripheral surface of the wiring board 10, and the outer peripheral surface of the second resin layer 116. The shield layer is connected to the ground terminal included in the plurality of external connection terminals 9 via a ground electrode of the core board 1, for example. The shield layer has electrical conductivity. Each of the RF modules 100, 100a, 100b, 100c, 100d is provided with the shield layer as an electromagnetic shield inside and outside the RF module 100, 100a, 100b, 100c, 100d. The shield layer may have, for example, a multilayer structure in which a plurality of metal layers are stacked one on top of another. However, this is only an example and should not be construed as limiting. Alternatively, the shield layer may also be a single metal layer. The metal layer includes either one type of metal or multiple types of metals. If the shield layer has a multilayer structure in which a plurality of metal layers are stacked one on top of another, then the shield layer may include, for example, a first stainless steel layer, a Cu layer on the first stainless steel layer, and a second stainless steel layer on the Cu layer. A material for each of the first stainless steel layer and the second stainless steel layer may be an alloy including Fe, Ni, and Cr. If the shield layer is a single metal layer, then the shield layer may be a Cu layer, for example.

Also, in the RF modules 100, 100a, 100b, 100c, 100d, in at least one of the plurality of first electronic components 6, one principal surface, opposite from the other principal surface facing the first buildup layer 2, of the at least one first electronic component 6 may be in contact with the shield layer without being covered with the first resin layer 115.

Furthermore, in the RF modules 100, 100a, 100b, 100c, 100d described above, the capacitor 8 is supposed to be a circuit element which forms part of the matching circuit. Alternatively, the capacitor 8 may also be a decoupling capacitor, a coupling capacitor, or a bypass capacitor.

### (Aspects)

The foregoing description of embodiments and their variations provides specific implementations of the following aspects of the present disclosure.

A radio frequency module (100; 100a; 100b) according to a first aspect includes a wiring board (10), an electronic component (6), an inductor (50), and a first shield portion (S1) and a second shield portion (S2). The electronic component (6) is disposed on the wiring board (10). The inductor (50) is built in the wiring board (10). The wiring board (10) includes a core board (1), a first buildup layer (2), and a second buildup layer (3). The core board (1) has not only a first principal surface (11) and a second principal surface (12) facing each other but also a through hole (14). The first buildup layer (2) is stacked on the first principal surface (11) of the core board (1). The second buildup layer (3) is stacked on the second principal surface (12) of the core board (1). The inductor (50) includes a magnetic core (4) and a coil (5). The magnetic core (4) is disposed inside the through hole (14) of the core board (1). The coil (5) is wound around the magnetic core (4). In this radio frequency module (100; 100a; 100b), an axis of winding (A5) of the coil (5) is perpendicular to a thickness direction (D1) defined for the core board (1). The first shield portion (S1) includes a first feedthrough ground via conductor (18). The first feedthrough ground via conductor (18) is provided for the core board (1). The second shield portion (S2) includes a second feedthrough ground via conductor (19). The second feedthrough ground via conductor (19) is provided for the core board (1). The first feedthrough ground via conductor (18) and the second feedthrough ground via conductor (19) are arranged to interpose the magnetic core (4) between the first feedthrough ground via conductor (18) and the second feedthrough ground via conductor (19) in a direction aligned with the axis of winding (A5) of the coil (5).

The radio frequency module (100; 100a; 100b) according to the first aspect may reduce the chances of causing a decline in the characteristics of the radio frequency module (100; 100a; 100b).

In a radio frequency module (100; 100a; 100b) according to a second aspect, which may be implemented in conjunction with the first aspect, when measured in the thickness direction (D1) defined for the core board (1), thickness (H4) of the magnetic core (4) is greater than thickness (H1) of the core board (1).

The radio frequency module (100; 100a; 100b) according to the second aspect may improve the characteristics of the inductor (50) compared to a situation where the thickness (H4) of the magnetic core (4) is equal to or less than the thickness (H1) of the core board (1).

A radio frequency module (100; 100a; 100b) according to a third aspect, which may be implemented in conjunction with the first or second aspect, includes a plurality of the first shield portions (S1) and a plurality of the second shield portions (S2). A plurality of the first feedthrough ground via conductors (18) included in the plurality of the first shield portions (S1) are arranged side by side in a direction perpendicular to not only the thickness direction (D1) defined for the core board (1) but also the axis of winding (A5) of the coil (5). A plurality of the second feedthrough ground via conductors (19) included in the plurality of the second shield portions (S2) are arranged side by side in the direction perpendicular to not only the thickness direction (D1) defined for the core board (1) but also the axis of winding (A5) of the coil (5).

The radio frequency module (100; 100a; 100b) according to the third aspect may further reduce the chances of causing a decline in isolation due to the magnetic flux produced by the coil (5).

A radio frequency module (100a; 100b) according to a fourth aspect, which may be implemented in conjunction with any one of the first to third aspects, further includes a capacitor (8) connected to the coil (5). The core board (1) further has a second through hole (15) different from a first through hole (14) serving as the through hole (14). The capacitor (8) is disposed inside the second through hole (15) of the core board (1). The capacitor (8) is located between the magnetic core (4) and the second feedthrough ground via conductor (19) when viewed in plan in the thickness direction (D1) defined for the core board (1).

The radio frequency module (100a; 100b) according to the fourth aspect may shorten the wire length between the coil (5) and the capacitor (8).

In a radio frequency module (100a) according to a fifth aspect, which may be implemented in conjunction with the fourth aspect, the capacitor (8) includes a first electrode (81) and a second electrode (82). In the first buildup layer (2), one of a plurality of via conductors (V1) included in the first buildup layer (2) is directly connected to the first electrode (81) of the capacitor (8), and another one of the plurality of via conductors (V1) included in the first buildup layer (2) is directly connected to the second electrode (82) of the capacitor (8). In the second buildup layer (3), one of a plurality of via conductors (V3) included in the second buildup layer (3) is directly connected to the first electrode (81) of the capacitor (8), and another one of the plurality of via conductors (V3) included in the second buildup layer (3) is directly connected to the second electrode (82) of the capacitor (8).

The radio frequency module (100a) according to the fifth aspect may adopt a configuration including no member for electrically connecting the first electrode (81) and second electrode (82) of the capacitor (8) to the core board (1).

In a radio frequency module (100b) according to a sixth aspect, which may be implemented in conjunction with the fourth aspect, the capacitor (8) includes a first electrode (81) and a second electrode (82). The core board (1) further includes: a first connection via conductor (17A) connected to the first electrode (81) of the capacitor (8); and a second connection via conductor (17B) connected to the second electrode (82) of the capacitor (8).

The radio frequency module (100b) according to the sixth aspect may adopt a configuration in which the capacitor (8) and the core board (1) are connected to each other.

A radio frequency module (100; 100a; 100b) according to a seventh aspect, which may be implemented in conjunction with any one of the first to sixth aspects, further includes, separately from a first electronic component (6) serving as the electronic component (6), a second electronic component (7) disposed on a principal surface (301), opposite from another principal surface facing the core board (1), of the second buildup layer (3).

The radio frequency module (100; 100a; 100b) according to the seventh aspect may contribute to reducing the size of the radio frequency module (100; 100a; 100b) when viewed in plan in the thickness direction (D1) defined for the core board (1).

In a radio frequency module (100; 100a; 100b) according to an eighth aspect, which may be implemented in conjunction with any one of the first to seventh aspects, the core board (1) is a double-sided printed wiring board.

A radio frequency module (100c; 100d) according to a ninth aspect includes a wiring board (10), an electronic component (6), an inductor (50), and a first shield portion (S11) and a second shield portion (S12). The electronic component (6) is disposed on the wiring board (10). The inductor (50c) is built in the wiring board (10). The wiring board (10) includes a core board (1), a first buildup layer (2), and a second buildup layer (3). The core board (1) has not only a first principal surface (11) and a second principal surface (12) facing each other but also a through hole (14). The first buildup layer (2) is stacked on the first principal surface (11) of the core board (1). The second buildup layer (3) is stacked on the second principal surface (12) of the core board (1). The inductor (50c) includes a magnetic core (4) and a coil (5c). The magnetic core (4) is disposed inside the through hole (14) of the core board (1). The coil (5c) is wound around the magnetic core (4). In this radio frequency module (100c; 100d), an axis of winding (A5c) of the coil (5c) is parallel to a thickness direction (D1) defined for the core board (1). The first shield portion (S11) includes a first ground conductor portion (27). The first ground conductor portion (27) is provided for the first buildup layer (2). The second shield portion (S12) includes a second ground conductor portion (37). The second ground conductor portion (37) is provided for the second buildup layer (3). The first ground conductor portion (27) and the second ground conductor portion (37) are arranged to interpose the magnetic core (4) between the first ground conductor portion (27) and the second ground conductor portion (37) in a direction aligned with the axis of winding (A5c) of the coil (5c).

The radio frequency module (100c; 100d) according to the ninth aspect may reduce the chances of causing a decline in the characteristics of the radio frequency module (100c; 100d).

In a radio frequency module (100c; 100d) according to a tenth aspect, which may be implemented in conjunction with the ninth aspect, when measured in the thickness direction (D1) defined for the core board (1), thickness (H4) of the magnetic core (4) is greater than thickness (H1) of the core board (1).

The radio frequency module (100c; 100d) according to the tenth aspect may improve the characteristics of the inductor (50c) compared to a situation where the thickness (H4) of the magnetic core (4) is equal to or less than the thickness (H1) of the core board (1).

A radio frequency module (100c; 100d) according to an eleventh aspect, which may be implemented in conjunction with the ninth or tenth aspect, includes a plurality of the first shield portions (S11) and a plurality of the second shield portions (S12). A plurality of the first ground conductor portions (27) included in the plurality of the first shield portions (S11) are arranged side by side in a direction perpendicular to the axis of winding (A5c) of the coil (5c). Aplurality of the second ground conductor portions (37) included in the plurality of the second shield portions (S12) are arranged side by side in the direction perpendicular to the axis of winding (A5c) of the coil (5c).

The radio frequency module (100c; 100d) according to the eleventh aspect may further reduce the chances of causing a decline in isolation due to the magnetic flux produced by the coil (5c).

In a radio frequency module (100c; 100d) according to a twelfth aspect, which may be implemented in conjunction with the eleventh aspect, the plurality of the first ground conductor portions (27) are arranged in either stripes or a combtooth pattern. The plurality of the second ground conductor portions (37) are arranged in either stripes or the combtooth pattern.

A radio frequency module (100c; 100d) according to a thirteenth aspect, which may be implemented in conjunction with any one of the ninth to twelfth aspects, further includes a capacitor (8) connected to the coil (5c). The core board (1) further has a second through hole (15) different from a first through hole (14) serving as the through hole (14). The capacitor (8) is disposed inside the second through hole (15) of the core board (1).

The radio frequency module (100c; 100d) according to the thirteenth aspect may contribute to reducing the size of the radio frequency module (100c; 100d) when viewed in plan in the thickness direction (D1) defined for the core board (1).

In a radio frequency module (100d) according to a fourteenth aspect, which may be implemented in conjunction with the thirteenth aspect, when viewed in plan in the thickness direction (D1) defined for the core board (1), the first ground conductor portion (27) included in the first shield portion (S11) overlaps with a part of the magnetic core (4) and a part of the capacitor (8). When viewed in plan in the thickness direction (D1) defined for the core board (1), the second ground conductor portion (37) included in the second shield portion (S12) overlaps with a part of the magnetic core (4) and a part of the capacitor (8).

The radio frequency module (100d) according to the fourteenth aspect may shield itself from the noise generated by a matching circuit including the coil (5c) and the capacitor (8).

In a radio frequency module (100c; 100d) according to a fifteenth aspect, which may be implemented in conjunction with any one of the ninth to fourteenth aspects, the first buildup layer (2) includes a plurality of first dielectric layers (20). The second buildup layer (3) includes a plurality of second dielectric layers (30). The first ground conductor portion (27) is formed directly on a first dielectric layer (21) located closer to the core board (1) in the thickness direction (D1) defined for the core board (1) than any other one of the plurality of first dielectric layers (20). The second ground conductor portion (37) is formed directly on a second dielectric layer (31) located closer to the core board (1) in the thickness direction (D1) defined for the core board (1) than any other one of the plurality of second dielectric layers (30).

The radio frequency module (100c; 100d) according to the fifteenth aspect may improve the shielding capability of the first shield portion (S11) and the second shield portion (S12).

A radio frequency module (100c; 100d) according to a sixteenth aspect, which may be implemented in conjunction with any one of the ninth to fifteenth aspects, further includes, separately from a first electronic component (6) serving as the electronic component (6), a second electronic component (7) disposed on a principal surface (301), opposite from another principal surface facing the core board (1), of the second buildup layer (3).

The radio frequency module (100c; 100d) according to the sixteenth aspect may contribute to reducing the size of the radio frequency module (100c; 100d) when viewed in plan in the thickness direction (D1) defined for the core board (1).

In a radio frequency module (100c; 100d) according to a seventeenth aspect, which may be implemented in conjunction with any one of the ninth to sixteenth aspects, the core board (1) is a double-sided printed wiring board.
1 Core Board
11 First Principal Surface
12 Second Principal Surface
13 Third Feedthrough Ground Via Conductor
14 Through Hole (First Through Hole)
15 Second Through Hole
16 Fourth Feedthrough Ground Via Conductor
17A First Connection Via Conductor
17B Second Connection Via Conductor
170 Feedthrough Via Conductor
171, 172, 173, 174, 175 Feedthrough Via Conductor
18 First Feedthrough Ground Via Conductor
19 Second Feedthrough Ground Via Conductor
101 Dielectric Substrate
111 First Principal Surface
112 Second Principal Surface
102 First Conductive Layer
121 Ground Conductor Portion
122 Ground Conductor Portion
103 Second Conductive Layer
131 Ground Conductor Portion
132 Ground Conductor Portion
2 First Buildup Layer
20 First Dielectric Layer
21 First Dielectric Layer
22 First Dielectric Layer
23 First Conductor Layer
24 First Conductor Layer
27 First Ground Conductor Portion
201 Principal Surface
3 Second Buildup Layer
30 Second Dielectric Layer
31 Second Dielectric Layer
32 Second Dielectric Layer
33 Second Conductor Layer
34 Second Conductor Layer
37 Second Ground Conductor Portion
371 First Part
372 Second Part
373 Third Part
301 Principal Surface
4 Magnetic Core
40 Outer Edge
41 Third Principal Surface
42 Fourth Principal Surface
45 First Side Surface
46 Second Side Surface
5, 5c Coil
50, 50c Inductor
520 First Conductor Portion
520A First End
520B Second End
521, 522, 523 First Conductor Portion
530 Second Conductor Portion
530A First End
530B Second End
531, 532, 533, 534 Second Conductor Portion
6 Electronic Component (First Electronic Component)
66 Bonding Portion
7 Second Electronic Component
76 Bonding Portion
8 Capacitor
81 First Electrode
82 Second Electrode
85 Fifth Principal Surface
86 Sixth Principal Surface
9 External Connection Terminal
91 First Ground Terminal
92 Second Ground Terminal
10 Wiring Board
100, 100a, 100b, 100c, 100d RF Module
115 First Resin Layer
116 Second Resin Layer
A5 Axis of Winding
B1 First Connection Portion
B2 Second Connection Portion
D1 Thickness Direction (First Direction)
D2 Second Direction
H1 Thickness
H4 Thickness
L18 Gap Distance
L19 Gap Distance
L27 Gap Distance
L37 Gap Distance
P1 Rewiring Portion
P2 Rewiring Portion
P3 Rewiring Portion
P4 Rewiring Portion
P21 Grounding Conductor Portion
P31 Grounding Conductor Portion
P32 Grounding Conductor Portion
P42 Grounding Conductor Portion
S1 First Shield Portion
S2 Second Shield Portion
S3 Third Shield Portion
S4 Fourth Shield Portion
S11 First Shield Portion
S12 Second Shield Portion
V1 Via Conductor
V2 Via Conductor
V3 Via Conductor
V4 Via Conductor
V21 Grounding Via Conductor
V22 Grounding Via Conductor
V31 Grounding Via Conductor
V32 Grounding Via Conductor
V33 Grounding Via Conductor
V34 Grounding Via Conductor
V42 Grounding Via Conductor
V51, V52, V53, V54, V55, V56 First Via Conductor
V61, V62, V63, V64, V65, V66 Second Via Conductor
W4 Length
W45 Length
W46 Length

1. A radio frequency module comprising:
a wiring board;
a first electronic component disposed on the wiring board;
an inductor built in the wiring board; and
a first shield portion and a second shield portion,
the wiring board including:
a core board having not only a first principal surface and a second principal surface facing each other but also a first through hole;
a first buildup layer stacked on the first principal surface of the core board; and
a second buildup layer stacked on the second principal surface of the core board,
the inductor including:
a magnetic core disposed inside the first through hole of the core board; and
a coil wound around the magnetic core,
an axis of winding of the coil being perpendicular to a thickness direction defined for the core board,
the first shield portion including a first feedthrough ground via conductor provided for the core board,
the second shield portion including a second feedthrough ground via conductor provided for the core board,
the first feedthrough ground via conductor and the second feedthrough ground via conductor being arranged to interpose the magnetic core between the first feedthrough ground via conductor and the second feedthrough ground via conductor in a direction aligned with the axis of winding.

2. The radio frequency module of claim 1, wherein
when measured in the thickness direction defined for the core board, a thickness of the magnetic core is greater than a thickness of the core board.

3. The radio frequency module of claim 1, wherein
the first shield portion comprises a plurality of first shield portions; and
the second shield portion comprises a plurality of second shield portions,
the plurality of first shield portions including a plurality of first feedthrough ground via conductors, and
the plurality of second shield portions including a plurality of second feedthrough ground via conductors, wherein
the plurality of first feedthrough ground via conductors are arranged side by side in a direction perpendicular to not only the thickness direction defined for the core board but also the axis of winding of the coil, and
the plurality of second feedthrough ground via conductors are arranged side by side in the direction perpendicular to not only the thickness direction defined for the core board but also the axis of winding of the coil.

4. The radio frequency module of claim 1, further comprising a capacitor connected to the coil, wherein
the core board further has a second through hole, the second through hole being different from the first through hole,
the capacitor is disposed inside the second through hole of the core board, and
the capacitor is located between the magnetic core and the second feedthrough ground via conductor when viewed in plan in the thickness direction defined for the core board.

5. The radio frequency module of claim 4, wherein
the capacitor includes a first electrode and a second electrode,
in the first buildup layer, one of a plurality of via conductors included in the first buildup layer is directly connected to the first electrode of the capacitor, and another one of the plurality of via conductors included in the first buildup layer is directly connected to the second electrode of the capacitor, and
in the second buildup layer, one of a plurality of via conductors included in the second buildup layer is directly connected to the first electrode of the capacitor, and another one of the plurality of via conductors included in the second buildup layer is directly connected to the second electrode of the capacitor.

6. The radio frequency module of claim 4, wherein
the capacitor includes a first electrode and a second electrode, and
the core board further includes:
a first connection via conductor connected to the first electrode of the capacitor; and
a second connection via conductor connected to the second electrode of the capacitor.

7. The radio frequency module of claim 1, further comprising, separately from the first electronic component, a second electronic component disposed on a principal surface, opposite from another principal surface facing the core board, of the second buildup layer.

8. The radio frequency module of claim 1, wherein
the core board is a double-sided printed wiring board.

9. A radio frequency module comprising:
a wiring board;
a first electronic component disposed on the wiring board;
an inductor built in the wiring board; and
a first shield portion and a second shield portion,
the wiring board including:
a core board having not only a first principal surface and a second principal surface facing each other but also a first through hole;
a first buildup layer stacked on the first principal surface of the core board; and
a second buildup layer stacked on the second principal surface of the core board,
the inductor including:
a magnetic core disposed inside the first through hole of the core board; and
a coil wound around the magnetic core,
an axis of winding of the coil being parallel to a thickness direction defined for the core board,
the first shield portion including a first ground conductor portion provided for the first buildup layer,
the second shield portion including a second ground conductor portion provided for the second buildup layer,
the first ground conductor portion and the second ground conductor portion being arranged to interpose the magnetic core between the first ground conductor portion and the second ground conductor portion in a direction aligned with the axis of winding.

10. The radio frequency module of claim 9, wherein
when measured in the thickness direction defined for the core board, a thickness of the magnetic core is greater than a thickness of the core board.

11. The radio frequency module of claim 9, wherein
the first shield portion comprises a plurality of first shield portions; and
the second shield portion comprises a plurality of second shield portions,
the plurality of first shield portions including a plurality of first feedthrough ground via conductors, and
the plurality of second shield portions including a plurality of second feedthrough ground via conductors, wherein
the plurality of first ground conductor portions are arranged side by side in a direction perpendicular to the axis of winding of the coil, and
the plurality of second ground conductor portions are arranged side by side in the direction perpendicular to the axis of winding of the coil.

12. The radio frequency module of claim 11, wherein
the plurality of the first ground conductor portions are arranged in either stripes or a combtooth pattern, and
the plurality of the second ground conductor portions are arranged in either stripes or the combtooth pattern.

13. The radio frequency module of claim 9, further comprising a capacitor connected to the coil, wherein
the core board further has a second through hole, the second through hole being different from the first through hole, and
the capacitor is disposed inside the second through hole of the core board.

14. The radio frequency module of claim 13, wherein
when viewed in plan in the thickness direction defined for the core board, the first ground conductor portion included in the first shield portion overlaps with a part of the magnetic core and a part of the capacitor, and
when viewed in plan in the thickness direction defined for the core board, the second ground conductor portion included in the second shield portion overlaps with a part of the magnetic core and a part of the capacitor.

15. The radio frequency module of claim 9, wherein
the first buildup layer includes a plurality of first dielectric layers,
the second buildup layer includes a plurality of second dielectric layers,
the first ground conductor portion is provided directly on a first dielectric layer located closer to the core board in the thickness direction defined for the core board than any other one of the plurality of first dielectric layers, and
the second ground conductor portion is provided directly on a second dielectric layer located closer to the core board in the thickness direction defined for the core board than any other one of the plurality of second dielectric layers.

16. The radio frequency module of claim 9, further comprising, separately from the first electronic component, a second electronic component disposed on a principal surface, opposite from another principal surface facing the core board, of the second buildup layer.

17. The radio frequency module of claim 9, wherein
the core board is a double-sided printed wiring board.

18. The radio frequency module of claim 2, wherein
the first shield portion comprises a plurality of first shield portions; and
the second shield portion comprises a plurality of second shield portions,
the plurality of first shield portions including a plurality of first feedthrough ground via conductors, and
the plurality of second shield portions including a plurality of second feedthrough ground via conductors, wherein
the plurality of first feedthrough ground via conductors are arranged side by side in a direction perpendicular to not only the thickness direction defined for the core board but also the axis of winding of the coil, and
the plurality of second feedthrough ground via conductors are arranged side by side in the direction perpendicular to not only the thickness direction defined for the core board but also the axis of winding of the coil.

19. The radio frequency module of claim 2, further comprising a capacitor connected to the coil, wherein
the core board further has a second through hole, the second through hole being different from the first through hole,
the capacitor is disposed inside the second through hole of the core board, and
the capacitor is located between the magnetic core and the second feedthrough ground via conductor when viewed in plan in the thickness direction defined for the core board.

20. The radio frequency module of claim 3, further comprising a capacitor connected to the coil, wherein
the core board further has a second through hole, the second through hole being different from the first through hole,
the capacitor is disposed inside the second through hole of the core board, and
the capacitor is located between the magnetic core and the second feedthrough ground via conductor when viewed in plan in the thickness direction defined for the core board.
